(19) United States
(12) Patent Application Publication
(10) Pub. No.: US 2011/0278666 A1
(43) Pub. Date: Nov. 17, 2011

(54) Trench MOSFET with integrated Schottky diode in a single cell and method of manufacture

(76) Inventors: Wei Liu, Suzhou (CN); Fan Wang, Suzhou (CN); Yichuan Cheng, Suzhou (CN)

(21) Appl. No.: 12/779,919

(22) Filed: May 13, 2010

(51) Int. Cl. H01L 27/06; H01L 21/336; H01L 21/8234

(52) U.S. Cl. 257/334; 438/237; 257/E21.616; 257/E21.41; 257/E27.016

(57) ABSTRACT

A trench MOSFET with integrated Schottky diode in a single cell includes a plurality of body regions extending to an epitaxial layer; a first trench extending through one of the body regions and reaching the epitaxial layer, the first trench being substantially filled by a conductive material that is separated from a sidewall of the first trench by a layer of dielectric material; and a second trench positioned between two adjacent body regions and extended into the epitaxial layer. Two source regions, two heavy body contact regions and the two adjacent body regions surround the second trench. The trench MOSFET further includes a Schottky diode having a metal layer formed along a sidewall and near a bottom of the second trench. In its manufacturing method, the spacer and self-alignment are processed two times, thus low cost and high reliability performance of the device are achieved at the same time.

### BACKGROUND OF THE PRESENT INVENTION

1. Field of Invention

The present invention relates to a semiconductor technology, and more particularly to a trench MOSFET with integrated Schottky diode in a single cell, and its method of manufacture.

2. Description of Related Arts

The trench MOSFET is the most widely used low-voltage (i.e. less than 200V) switch. FIG. 1 shows a circuit schematic for a dc/dc converter. Two trench MOSFET M1 (low-side) and M2 (high-side) can be found: firstly, when M1 and M2 are both OFF to prevent shoot-through, in order to keep the current at the load uninterrupted, the body diode of M1, which is formed by P-body and drain, need forward biased to conduction. Instead of the MOSFET body diode, a paralleled Schottky diode is preferred for its lower turn-on voltage; secondly, it's known that when the paralleled Schottky diode is the turned-on component, the time to turn it off (reverse recovery) is effectively shortened, which means less switching power loss.

For many years, discrete packaged Schottky diodes are mounted on the PCB, which result in occupying more PCB area, high cost, and more transient-related side effects. More recently, some manufacturers have introduced products in which a Schottky diode and a trench MOSFET chip are housed in same package, which still result in big package area and high cost. There have also been monolithic implementations of power MOSFETs with Schottky diode which are illustrated as follows.

FIG. 2 is a cross sectional view of a trench MOSFET device integrated with trench Schottky diodes as that disclosed by U.S. Pat. No. 6,351,018. The interspersed Schottky diodes consume additional silicon area. Furthermore, additional masks are needed to prevent the P-body, N+ source, and P+ heavy body in the Schottky area.

In U.S. Pat. No. 6,433,396, a trench MOSFET device with a planar Schottky diode is disclosed as that shown in FIG. 3. The configuration has the disadvantage that the planar Schottky diodes occupy additional space.

U.S. Pat. No. 7,446,374 discloses a trench MOSFET device with integrated Schottky diodes, as shown in FIG. 4. The configuration as disclosed in the patented invention again has the disadvantage of additional silicon area occupation: the P+ heavy body region extend through N− region leads to no Schottky diode formation in this region. And when working under very fast switching condition, more P+ heavy body area is needed to prevent the parasitic bipolar (N+ source/P-body/N+ drain) from turning on. Furthermore, additional mask is needed to pattern the P+ heavy body regions.

Therefore, there is still a need for an integrated Schottky diode and trench MOSFET with superior performance characteristics to resolve the above discussed technical limitations.

### SUMMARY OF THE PRESENT INVENTION

An object of the present invention is to provide a trench MOSFET with integrated Schottky diode in a single cell, and its method of manufacture, wherein power loss of the trench MOSFET is effectively reduced and gives high device performance.

Another object of the present invention is to provide a trench MOSFET with integrated Schottky diode in a single cell, and its method of manufacture, wherein source, P+ heavy body, and Schottky diode anode share the same contact, so that the silicon area is saved to lower manufacturing cost, and the device performance is promoted simultaneously.

Another object of the present invention is to provide a trench MOSFET with integrated Schottky diode in a single cell, and its method of manufacture, wherein no additional mask and photo process are needed for the Schottky diode module.

Another object of the present invention is to provide a trench MOSFET with integrated Schottky diode in a single cell, and its method of manufacture, wherein the method of manufacture involving dielectric spacer (oxide or nitride) and self-alignment technologies are disclosed to achieve low cost and high reliability performance of the device at the same time.

Accordingly, in order to accomplish the above objects, the present invention provides a trench MOSFET with integrated Schottky diode in a single cell, comprising:

a plurality of body regions extending to a predetermined depth within an epitaxial layer;

a first trench extending through one of the body regions and reaching the epitaxial layer below the body regions, the first trench being substantially filled by a conductive material that is separated from a sidewall of the first trench by a layer of dielectric material forming a trench gate;

a second trench positioned between two adjacent body regions and extended into the epitaxial layer;

a pair of source regions positioned at opposite sides of the second trench and upper ends of said two adjacent body regions respectively;

a pair of heavy body contact regions positioned underneath the source regions respectively, and within said two adjacent body regions respectively, so that the source regions, the heavy body contact regions and the two adjacent body regions surround the second trench;

a dielectric spacer with proper thickness deposited on source regions at opposite sides of the first trench and on the first trench therebetween, wherein a size of the dielectric spacer determines that of the heavy body contact regions; and

an integrated Schottky diode formed near a bottom of the second trench having a metal layer along a sidewall of the second trench and on a surface of said epitaxial layer.

These and other objectives, features, and advantages of the present invention will become apparent from the following detailed description, the accompanying drawings, and the appended claims.

### BRIEF DESCRIPTION OF THE DRAWINGS

FIG. 1 is a circuit schematic for a dc/dc converter using power MOSFET with a Schottky diode at the low side.

FIGS. 2 to 4 are cross-sectional views of MOSFET power devices of related disclosures of conventional device configurations implemented with various Schottky diode integrations.

FIG. 5 is a cross-sectional view of a trench MOSFET with integrated Schottky diode in a single cell, and its method of manufacture according to a first preferred embodiment of the present invention.

FIGS. 6A to 6F are a serial of side cross sectional views for showing the processing steps for fabricating a trench MOSFET with integrated Schottky diode in a single cell as shown in FIG. 5 of the present invention.

FIG. 7 is a cross-sectional view of a trench MOSFET with integrated Schottky diode in a single cell, and its method of manufacture according to a second preferred embodiment of the present invention.

FIGS. 8A to 8B illustrate the fabrication process of the thicker bottom gate oxide shown in FIG. 7.

FIG. 9 is a cross-sectional view of a trench MOSFET with integrated Schottky diode in a single cell, and its method of manufacture according to a third preferred embodiment of the present invention.

FIGS. 10A to 10B illustrate the fabrication process of the shield poly shown in FIG. 9.

FIG. 11 is a cross-sectional view of a trench MOSFET with integrated Schottky diode in a single cell, and its method of manufacture according to a fourth preferred embodiment of the present invention.

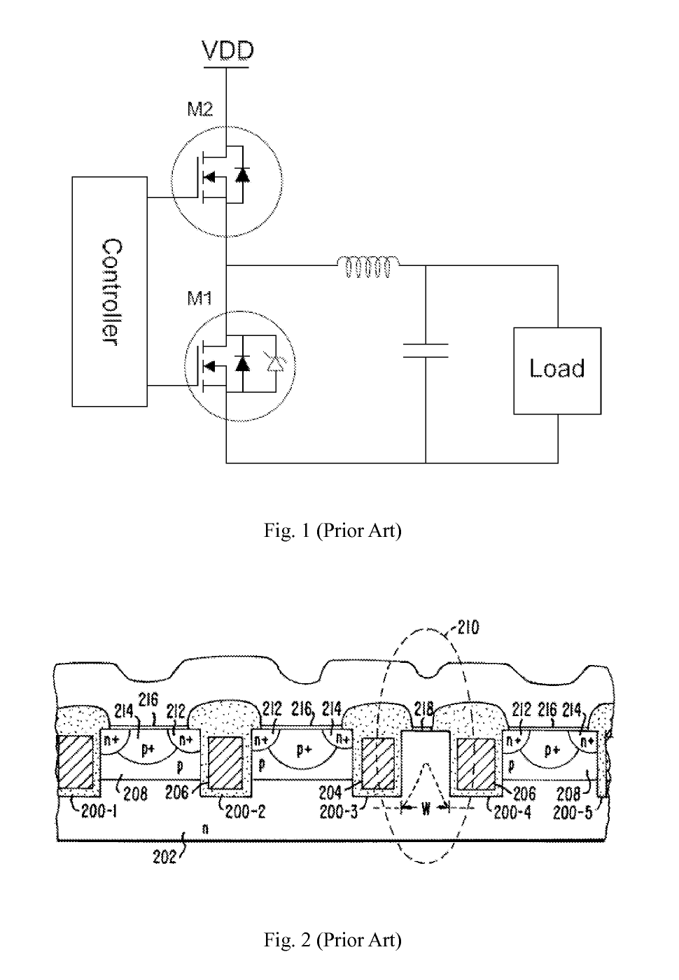

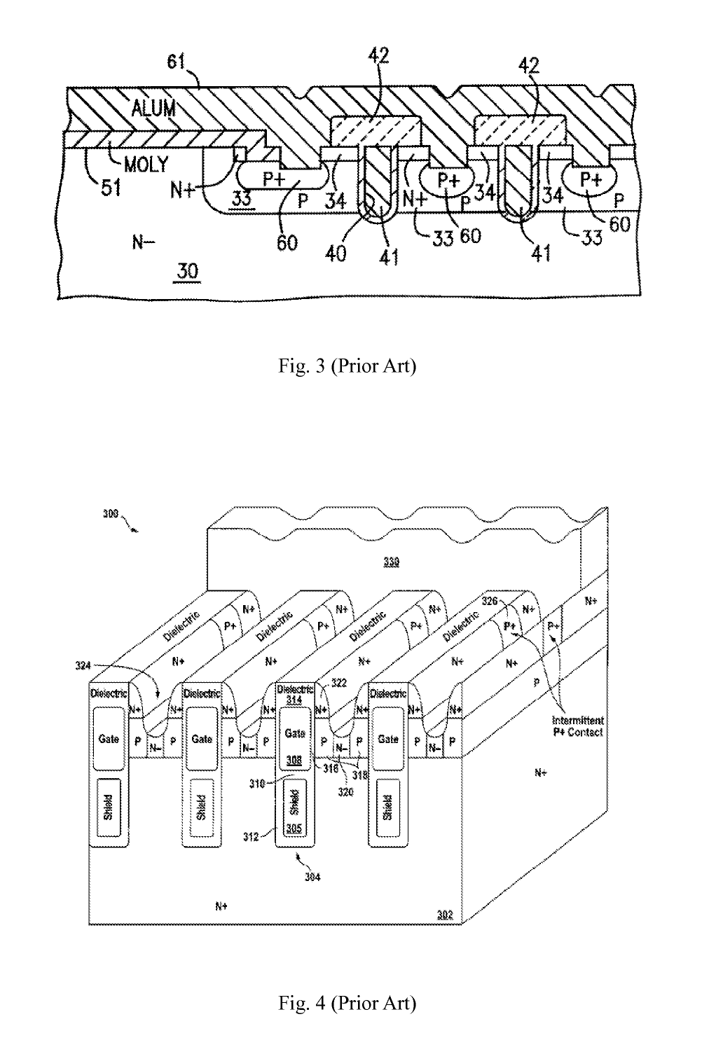

### DETAILED DESCRIPTION OF THE PREFERRED EMBODIMENT

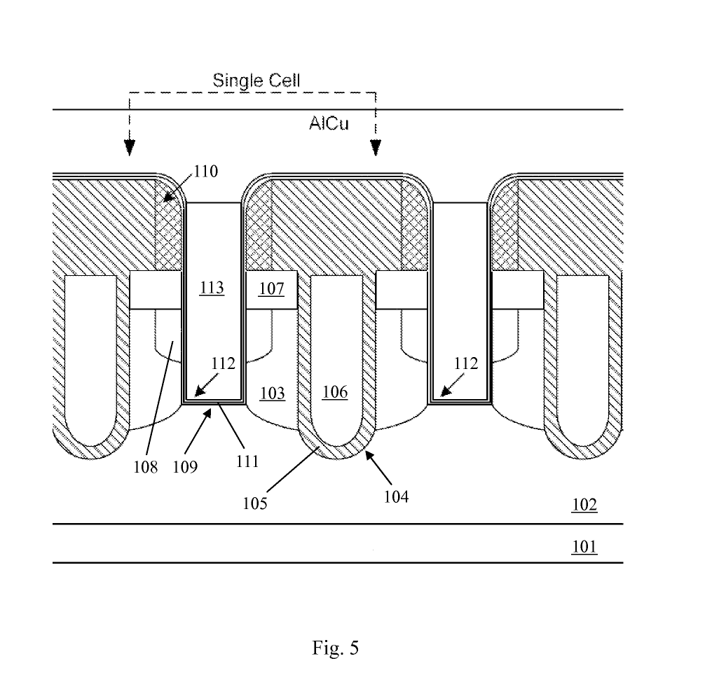

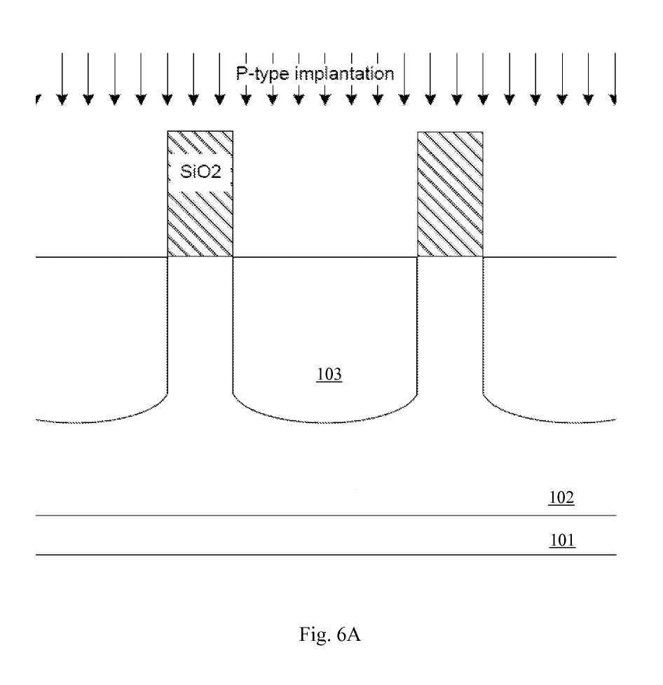

Referring to FIG. 5, a trench MOSFET 100 with integrated Schottky diode in a single cell according to a first preferred embodiment of the present invention is illustrated. The trench MOSFET 100 is supported on an N+ substrate 101 formed with an N-type epitaxial layer 102.

The trench MOSFET 100 comprises a plurality of P-body regions 103 spaced from each other and extended to a predetermined depth within the N-type epitaxial layer 102. A first trench 104 extends through one of the P-body regions 103 and reaches the N-type epitaxial layer 102 below one of the P-body regions 103. A trench gate 106 is deposited within the first trench 104 that is separated by a gate oxide layer 105.

A second trench 109 is positioned between two adjacent P-body regions 103 and extended into the N-type epitaxial layer 102. A pair of N+ source regions 107 are positioned at opposite sides of the second trench 109, and upper ends of the two adjacent P-body regions 103 respectively. A pair of P+ heavy body contact regions 108 are positioned underneath the N+ source regions 107 and within the two adjacent P-body regions 103 respectively. Therefore, the N+ source regions 107, the P+ heavy body contact regions 108 and the two adjacent P-body regions 103 surround the second trench 109. A dielectric spacer 110 (oxide or nitride) with proper thickness is deposited on the N+ source regions 107 at opposite sides of the first trench 104, and on the first trench 104 therebetween.

It is worth mentioning that a size of the P+ heavy body contact regions 108 is determined by that of the dielectric spacer 110.

According to the present invention, a titanium glue layer 111 is formed on the dielectric spacer 110, along a sidewall of the second trench 109 and on the N-type epitaxial layer 102. A titanium nitride barrier layer 112 is formed on the titanium glue layer 111. Therefore, an integrated Schottky diode is formed near a bottom of the second trench 109 with the N-type epitaxial layer 102, the titanium glue layer 111 and the titanium nitride barrier layer 112. It is worth mentioning that the Schottky diode is integrated in every single cell, as shown in FIG. 5.

Furthermore, the second trench 109 can be filled with a tungsten plug 113. Accordingly, the integrated Schottky diode is formed near a bottom of the second trench 109 below the tungsten plug 113.

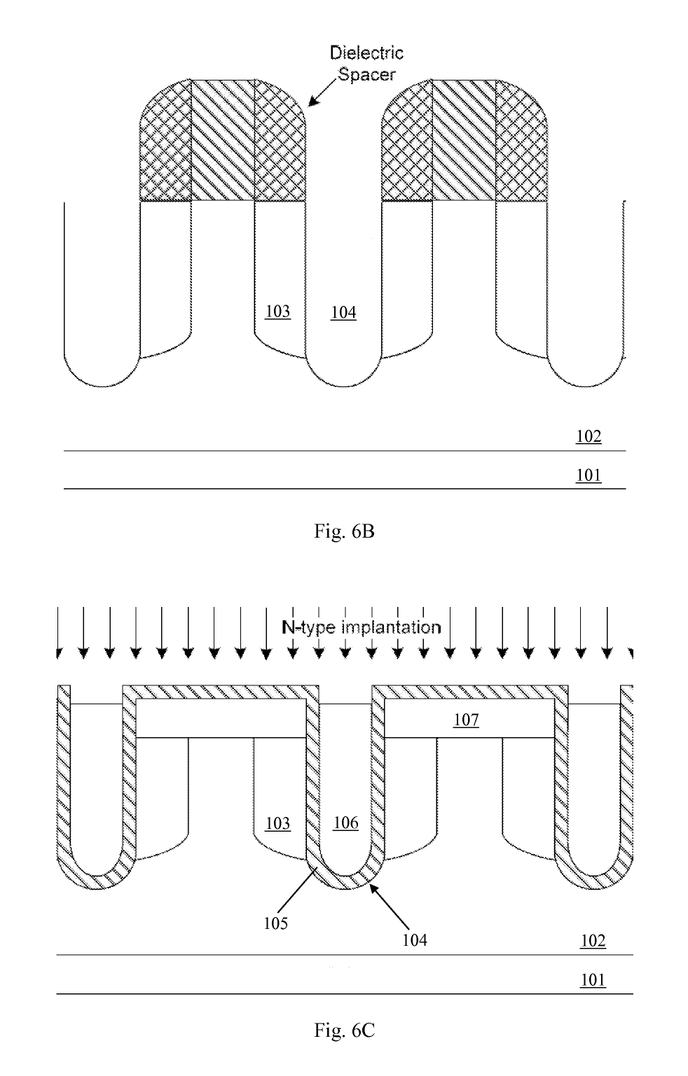

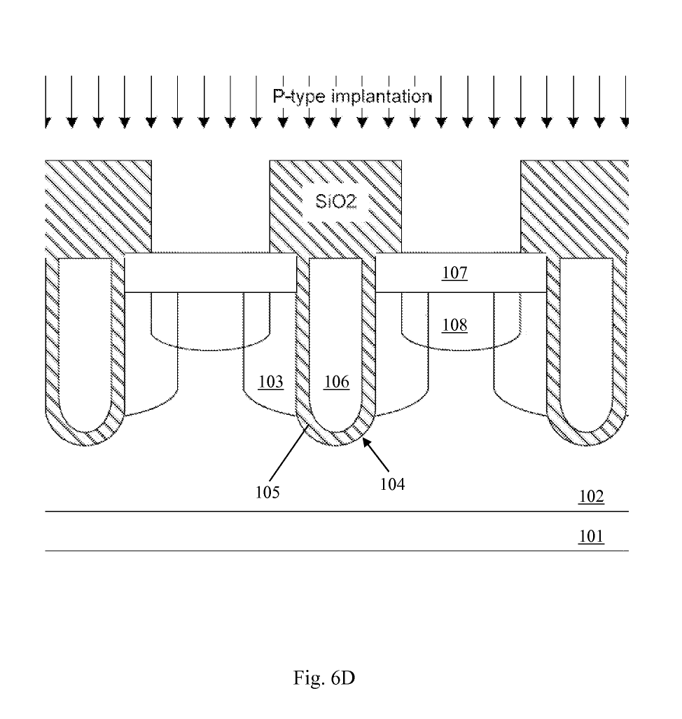

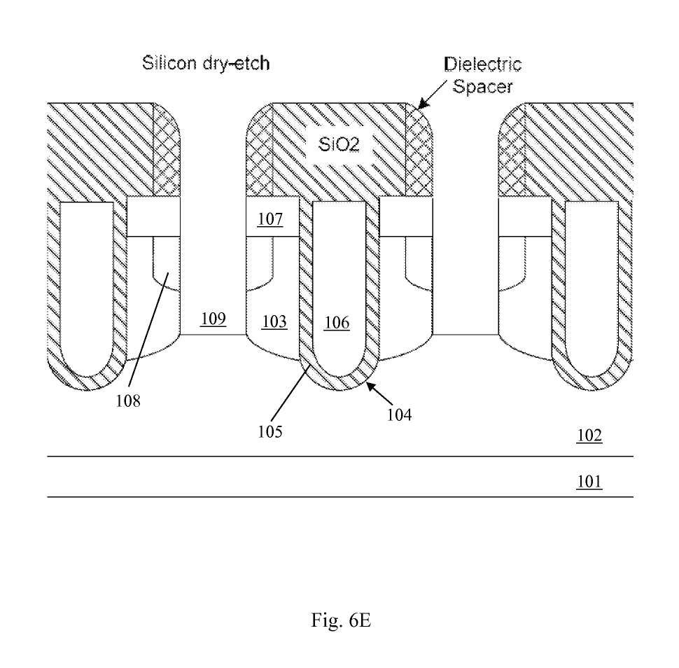

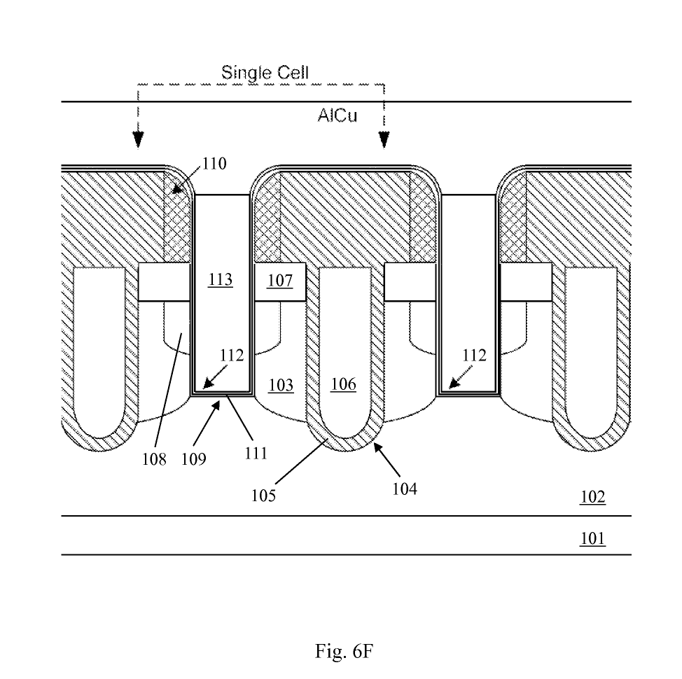

Referring to FIGS. 6A to 6F for a serial of side cross sectional views to illustrate the fabrication steps of a trench MOSFET with integrated Schottky diode in a single cell as that shown in FIG. 5. In FIG. 6A, an N+ substrate 101 is prepared as the drain of the MOSFET, and an N type epi-layer 102 is grown on the N+ substrate 101. An oxide layer is grown on the N-type epi-layer 102. Then a photo mask is used to pattern the P-body regions 103. After oxide layer dry etch, the photo-resist is removed. A P-type implantation is performed, using the remained oxide as hard-mask. Posting a rapid thermal annealing for dopant activation, the P-body regions 103 are formed inside the N-type epi-layer 102, with proper space and spaced from each other.

In FIG. 6B, a dielectric layer (oxide or nitride) with proper thickness is deposited on the entire structure. After a dielectric layer dry etch, the dielectric spacer around the oxide hard mask is formed. Then a silicon dry etch is performed, which makes a plurality of first trenches 104 through the P-body regions 103 respectively and into the N-type epi-layer 102. A proper enclosure of the P-body regions 103 to the first trenches 104 respectively is achieved.

In FIG. 6C, the oxide hard-mask and dielectric spacer is removed by wet etch. A gate oxide layer 105 is grown along an interior sidewall of the first trenches 104. Then an N+ polysilicon deposition and dry etch are performed, thereby forming a trench gate 106 within one of the first trenches 104. Then a photo mask is used to perform an N-type implantation. Posting photo-resist removing and a thermal treatment, an N+ source region 107 is formed between two adjacent first trenches 104.

In FIG. 6D, an oxide layer is deposited on the entire structure, and then a photo mask is used to define the source contact. After the oxide layer dry etch, which stopped on the silicon surface, the photo-resist is removed. Using the remained oxide as hard-mask, a P-type implantation is performed. Posting a rapid thermal annealing for dopant activation, a P+ heavy body contact region 108 is formed between two adjacent P-body regions 103 and underneath the N+ source region 107.

In FIG. 6E, a dielectric layer (oxide or nitride) with proper thickness is deposited on the entire structure. After a dielectric layer dry etch, the dielectric spacer around the oxide hard mask is formed. Then a silicon dry etch is performed, which makes a plurality of second trenches 109 into the N-type epi-layer 102 and between two adjacent P-body regions 103. Accordingly, a pair of N+ source regions 107 are positioned at opposite sides of one of the second trenches 109, and upper ends of two adjacent P-body regions 103. A pair of P+ heavy body contact regions 108 are positioned underneath the N+ source regions 107 respectively, and positioned within two adjacent P-body regions 103. As a result, the N+ source regions 107, the P+ heavy body contact regions 108, the two adjacent P-body regions 103, and the N-type epi-layer 102 surround one of the second trenches 109.

In FIG. 6F, Ti/TiN layers are deposited on the entire structure. A titanium glue layer 111 is formed on the dielectric spacer 110, along a sidewall of the second trench 109 and on the N-type epitaxial layer 102. A titanium nitride barrier layer 112 is formed on the titanium glue layer 111. Posting a thermal treatment, the N+ source ohmic contact, P+ heavy body ohmic contact, and N-EPI Schottky contact are formed. Then tungsten deposition and dry etch are performed to form the tungsten contact plug. If the contacts had big dimension, the tungsten contact plug processes could be omitted. Metal layer is deposited, and a photo mask is used to pattern the source and gate electrodes (the gate electrode is not illustrated in the drawings). Drain electrode is formed on the rear face of the substrate and not illustrated in the drawings. The source and drain electrodes of MOSFET are also anode and cathode electrodes of the integrated Schottky diodes.

According to the above drawings and descriptions, this invention further discloses a method of manufacturing a trench MOSFET with integrated Schottky diode in a single cell, comprising the steps of:

forming a plurality of body regions extending in parallel and into an epitaxial layer grown on a substrate;

forming a plurality of first trenches through the body regions respectively and into the epitaxial layer below the body regions;

forming a trench gate within one of the first trenches that is separated by a dielectric layer;

forming a source region between two adjacent first trenches along a top surface of the body regions and the epitaxial layer;

forming a heavy body contact region underneath the source region, and in the body regions and the epitaxial layer positioned between two adjacent first trenches;

forming a second trench between two adjacent body regions through the source region and the heavy body contact region into the epitaxial layer in such a manner that a pair of source regions and a pair of heavy body contact regions are positioned at opposite sides of the second trench respectively, so that the source regions, the heavy body contact regions and the two adjacent body regions surround the second trench;

forming a dielectric spacer with proper thickness on source regions at opposite sides of the first trench and on the first trench therebetween, wherein a size of the heavy body contact regions is determined by that of the dielectric spacer; and

forming an integrated Schottky diode in the second trench by forming a metal layer along a sidewall of the second trench and near a bottom of the second trench.

In the above mentioned method of manufacturing a trench MOSFET with integrated Schottky diode in a single cell, the Schottky diode is integrated in every single cell (as shown in FIG. 5), thus the switching loss of this trench MOSFET is effectively reduced and gives high device performance

Furthermore, source, P+ heavy body, and Schottky diode anode share the same contact, thus the silicon area is saved, which leads to low cost and high device performance.

Furthermore, no additional mask and photo process are needed for the Schottky diode module. The manufacture methods involving dielectric spacer (oxide or nitride) and self-alignment technologies are disclosed in this invention. The spacer and self-alignment are processed two times:

1^{st} in P-body implantation and trench etch (as shown in FIG. 6B); Using the patterned oxide hard-mask, a spaced region between P-body is made, that permits enough margin for the N-type epi-layer to be contacted by the source and P+ heavy body contact, and forms the Schottky contact; Then the dielectric spacer is processed, followed by a trench etch; A perfect enclosure of the P-body to the gate trench is achieved.

2^{nd} in P+ heavy body and Schottky contact etch (as shown in FIG. 5); Posting inter-layer oxide etch, a P+ implantation are done. The dielectric spacer here makes sure enough P+ region are saved to post the Schottky contact etch; The P+ region is very important in forming an ohmic contact for the P-body, and constraining the turning on of the parasitic NPN (N+ source/P-body/N-epi&N+ substrate) bipolar transistor;

Through the dielectric spacer and self-alignment process, low cost and high reliability performance of the device will be achieved at the same time.

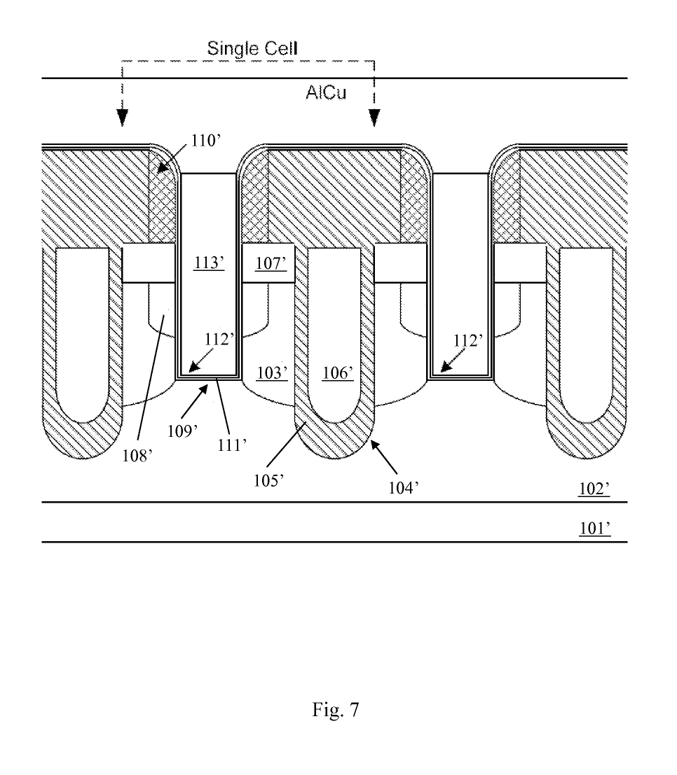

Referring to FIG. 7, a trench MOSFET with integrated Schottky diode in a single cell according to a second preferred embodiment of the present invention is illustrated. Similarly, the trench MOSFET, supported on an N+ substrate 101′ formed with an N-type epitaxial layer 102′, comprising a plurality of P-body regions 103′ spaced from each other and extended to a predetermined depth within the N-type epitaxial layer 102′. A first trench 104′ extends through one of the P-body regions 103′ and reaches the N-type epitaxial layer 102′ below one of the P-body regions 103′. A trench gate 106′ is deposited within the first trench 104′ that is separated by a gate oxide layer 105′.

A second trench 109′ is positioned between two adjacent P-body regions 103′ and extended into the N-type epitaxial layer 102′. A pair of N+ source regions 107′ are positioned at opposite sides of the second trench 109′, and upper ends of the two adjacent P-body regions 103′ respectively. A pair of P+ heavy body contact regions 108′ are positioned underneath the N+ source regions 107′ and within the two adjacent P-body regions 103′ respectively. Therefore, the N+ source regions 107′, the P+ heavy body contact regions 108′ and the two adjacent P-body regions 103′ surround the second trench 109′. A dielectric spacer 110′ (oxide or nitride) with proper thickness is deposited on the N+ source regions 107′ at opposite sides of the first trench 104′, and on the first trench 104′ therebetween.

It is worth mentioning that a size of the P+ heavy body contact regions 108′ is determined by that of the dielectric spacer 110′.

According to the present invention, a titanium glue layer 111′ is formed on the dielectric spacer 110′, along a sidewall of the second trench 109′ and on the N-type epitaxial layer 102′. A titanium nitride barrier layer 112′ is formed on the titanium glue layer 111′. Therefore, an integrated Schottky diode is formed near a bottom of the second trench 109′ with the N-type epitaxial layer 102′, the titanium glue layer 111′ and the titanium nitride barrier layer 112′. It is worth mentioning that the Schottky diode is integrated in every single cell, as shown in FIG. 7.

Furthermore, the second trench 109′ can be filled with a tungsten plug 113′. Accordingly, the integrated Schottky diode is formed near a bottom of the second trench 109′ below the tungsten plug 113′.

The trench MOSFET has a layer of thicker gate oxide 105′ at the bottom of a first trench 104′. The main benefit of thicker bottom gate oxide is smaller coupled capacitance between the poly gate 106′ and the N-type epi-layer 102′ (drain), which leads to less switching power loss. And also, the bigger thickness gives better break down performance when facing strong electric field stress when the channel turned off.

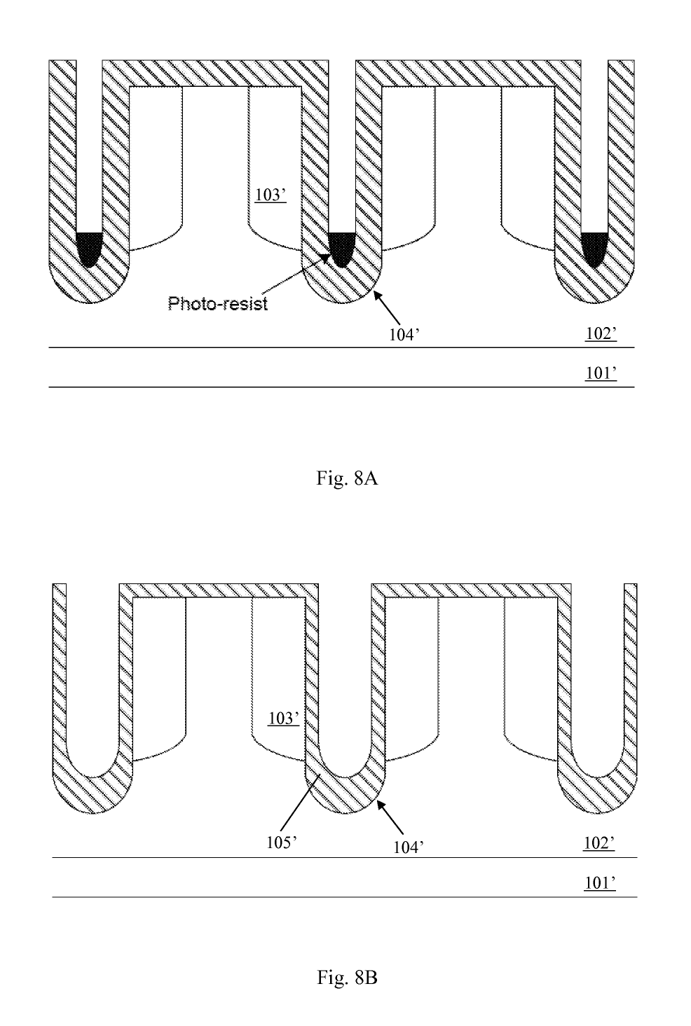

FIGS. 8A to 8B illustrate the fabrication process of the thicker bottom gate oxide.

Referring to FIG. 8A, after the P-body regions 103′ and first trenches 104′ forming, an oxide layer is grown. Photo-resist is coated on the entire structure. Without photo mask, the photo-resist is dry etched, with proper quantity remaining inside the first trenches.

In FIG. 8B, an oxide layer wet etch is performed, using the remained photo-resist as mask. Then after the remained photo-resist removing, an oxide layer is grown as gate oxide.

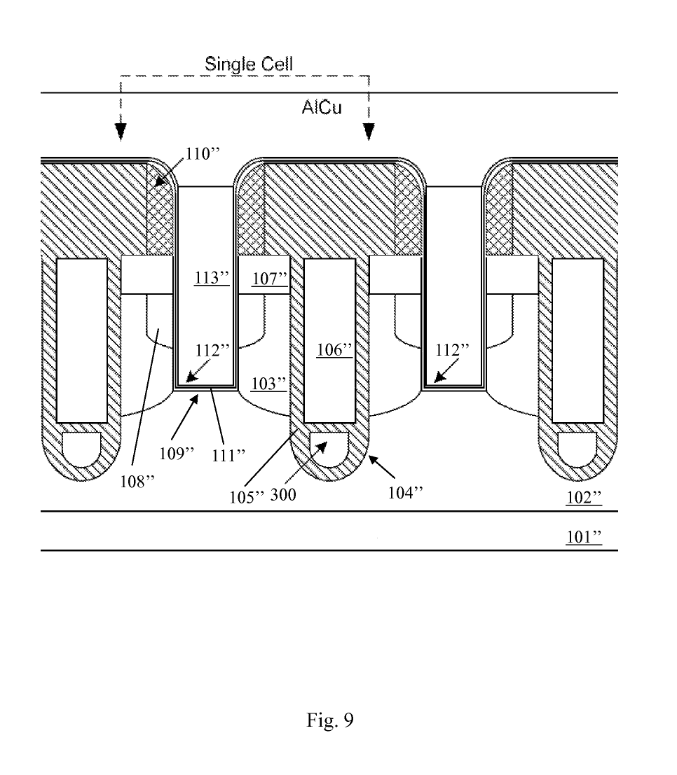

Referring to FIG. 9, a trench MOSFET with integrated Schottky diode in a single cell according to a third preferred embodiment of the present invention is illustrated. Similarly, the trench MOSFET, supported on an N+ substrate 101″ formed with an N-type epitaxial layer 102″, comprising a plurality of P-body regions 103″ spaced from each other and extended to a predetermined depth within the N-type epitaxial layer 102″. A first trench 104″ extends through one of the P-body regions 103″ and reaches the N-type epitaxial layer 102″ below one of the P-body regions 103″. A trench gate 106″ is deposited within the first trench 104″ that is separated by a gate oxide layer 105″.

A second trench 109″ is positioned between two adjacent P-body regions 103″ and extended into the N-type epitaxial layer 102″. A pair of N+ source regions 107″ are positioned at opposite sides of the second trench 109″, and upper ends of the two adjacent P-body regions 103″ respectively. A pair of P+ heavy body contact regions 108″ are positioned underneath the N+ source regions 107″ and within the two adjacent P-body regions 103″ respectively. Therefore, the N+ source regions 107″, the P+ heavy body contact regions 108″ and the two adjacent P-body regions 103″ surround the second trench 109″. A dielectric spacer 110″ (oxide or nitride) with proper thickness is deposited on the N+ source regions 107″ at opposite sides of the first trench 104″, and on the first trench 104″ therebetween.

It is worth mentioning that a size of the P+ heavy body contact regions 108″ is determined by that of the dielectric spacer 110″.

According to the present invention, a titanium glue layer 111″ is formed on the dielectric spacer 110″, along a sidewall of the second trench 109″ and on the N-type epitaxial layer 102″. A titanium nitride barrier layer 112″ is formed on the titanium glue layer 111″. Therefore, an integrated Schottky diode is formed near a bottom of the second trench 109″ with the N-type epitaxial layer 102″, the titanium glue layer 111″ and the titanium nitride barrier layer 112″. It is worth mentioning that the Schottky diode is integrated in every single cell, as shown in FIG. 9.

Furthermore, the second trench 109″ can be filled with a tungsten plug 113″. Accordingly, the integrated Schottky diode is formed near a bottom of the second trench 109″ below the tungsten plug 113″.

The trench MOSFET has a shield poly 300 at the bottom of the first trench. The main benefit of the shield poly is smaller coupled capacitance between the poly gate 106″ and the N-type epi-layer 102″ (drain), which leads to less switching power loss.

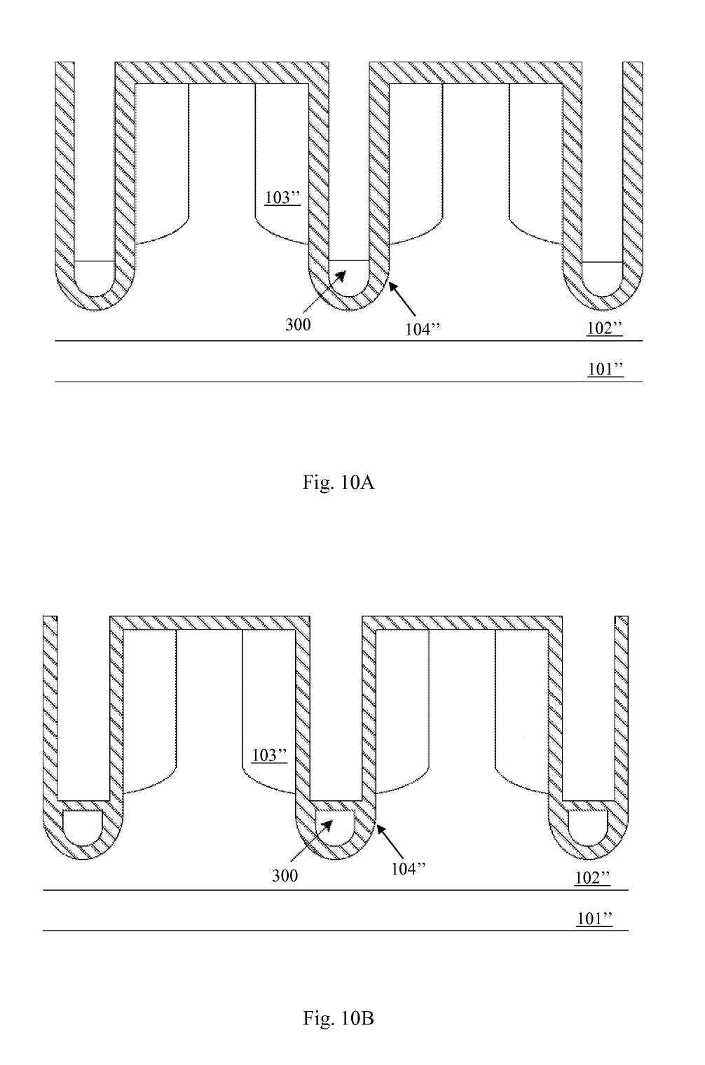

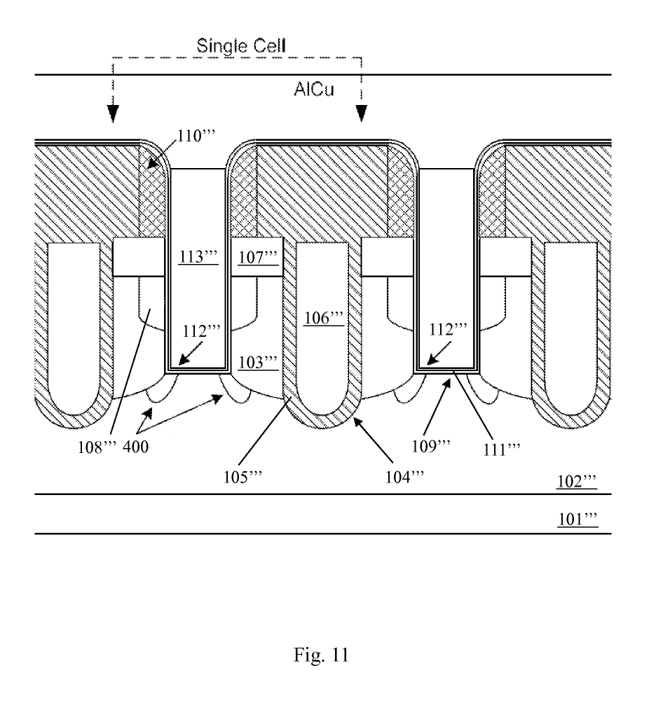

FIGS. 10A to 10B illustrate the fabrication process of the shield poly 300.

In FIG. 10A, after the P-body regions 103″ and first trench 104″ forming, an oxide layer is grown. A polysilicon layer is deposited on the entire structure. Without photo mask, the polysilicon is dry etched, with proper quantity remaining inside the first trench.

In FIG. 10B, an oxide layer wet etch is performed, using the remained polysilicon as hard-mask. Then an oxide layer is grown as gate oxide.

Referring to FIG. 11, a trench MOSFET with integrated Schottky diode in a single cell according to a fourth preferred embodiment of the present invention is illustrated. Similarly, the trench MOSFET, supported on an N+ substrate 101′″ formed with an N-type epitaxial layer 102′″, comprising a plurality of P-body regions 103′″ spaced from each other and extended to a predetermined depth within the N-type epitaxial layer 102′″. A first trench 104′″ extends through one of the P-body regions 103′″ and reaches the N-type epitaxial layer 102′″ below one of the P-body regions 103′″. A trench gate 106′″ is deposited within the first trench 104′″ that is separated by a gate oxide layer 105′.

A second trench 109′″ is positioned between two adjacent P-body regions 103′″ and extended into the N-type epitaxial layer 102′″. A pair of N+ source regions 107′″ are positioned at opposite sides of the second trench 109′″, and upper ends of the two adjacent P-body regions 103′″ respectively. A pair of P+ heavy body contact regions 108′″ are positioned underneath the N+ source regions 107′″ and within the two adjacent P-body regions 103′″ respectively. Therefore, the N+ source regions 107′″, the P+ heavy body contact regions 108′″ and the two adjacent P-body regions 103′″ surround the second trench 109′″. A dielectric spacer 110′ (oxide or nitride) with proper thickness is deposited on the N+ source regions 107′″ at opposite sides of the first trench 104′″, and on the first trench 104′″ therebetween.

It is worth mentioning that a size of the P+ heavy body contact regions 108′″ is determined by that of the dielectric spacer 110′″.

According to the present invention, a titanium glue layer 111′ is formed on the dielectric spacer 110′″, along a sidewall of the second trench 109′ and on the N-type epitaxial layer 102′″. A titanium nitride barrier layer 112′″ is formed on the titanium glue layer 111′″. Therefore, an integrated Schottky diode is formed near a bottom of the second trench 109′″ with the N-type epitaxial layer 102′″, the titanium glue layer 111′″ and the titanium nitride barrier layer 112′″. It is worth mentioning that the Schottky diode is integrated in every single cell, as shown in FIG. 11.

Furthermore, the second trench 109′″ can be filled with a tungsten plug 113′″. Accordingly, the integrated Schottky diode is formed near a bottom of the second trench 109′″ below the tungsten plug 113′″.

The trench MOSFET has additional P-type tilt angle regions 400 positioned underneath and at the opposite sides of the second trenches 109′″, within the N-type epi-layer 102′″. The additional P-type tilt angle regions 400 can be used to decrease the Schottky diode's revering leakage. Posting the second trenches etch, a tilt angle implantation is performed thus forming a pair of P-type tilt angle regions 400. Utilizing the shadowing of second trench sidewall, the bottom of the contact still connects with the N-type epi-layer 102′.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A trench MOSFET with integrated Schottky diode in a single cell, comprising:
a plurality of body regions extending to a predetermined depth within an epitaxial layer;
a first trench extending through one of said body regions and reaching said epitaxial layer below said body regions, said first trench being substantially filled by a conductive material that is separated from a sidewall of said first trench by a layer of dielectric material forming a trench gate;
a second trench positioned between two adjacent body regions and extended into said epitaxial layer;
a pair of source regions positioned at opposite sides of said second trench and upper ends of said two adjacent body regions respectively;
a pair of heavy body contact regions positioned underneath said source regions respectively, and within said two adjacent body regions respectively, so that said source regions, said heavy body contact regions and said two adjacent body regions surround said second trench;
a dielectric spacer with proper thickness deposited on source regions at opposite sides of said first trench and on said first trench therebetween, wherein a size of said dielectric spacer determines that of said heavy body contact regions; and
an integrated Schottky diode formed near a bottom of said second trench having a metal layer along a sidewall of said second trench and on a surface of said epitaxial layer.

2. The trench MOSFET with integrated Schottky diode in a single cell, as recited in claim 1, wherein said integrated Schottky diode further has a barrier layer formed on said metal layer, said second trench is filled with a tungsten plug separated from said metal layer by said barrier layer.

3. The trench MOSFET with integrated Schottky diode in a single cell, as recited in claim 1, wherein a thickness of a bottom of said layer of dielectric material is bigger than that of a sidewall of said layer of dielectric material.

4. The trench MOSFET with integrated Schottky diode in a single cell, as recited in claim 2, wherein a thickness of a bottom of said layer of dielectric material is bigger than that of a sidewall of said layer of dielectric material.

5. The trench MOSFET with integrated Schottky diode in a single cell, as recited in claim 1, wherein said first trench comprises a shield poly within a bottom portion of said layer of dielectric material.

6. The trench MOSFET with integrated Schottky diode in a single cell, as recited in claim 2, wherein said first trench comprises a shield poly within a bottom portion of said layer of dielectric material.

7. The trench MOSFET with integrated Schottky diode in a single cell, as recited in claim 5, wherein a thickness of a bottom of said layer of dielectric material is bigger than that of a sidewall of said layer of dielectric material.

8. The trench MOSFET with integrated Schottky diode in a single cell, as recited in claim 6, wherein a thickness of a bottom of said layer of dielectric material is bigger than that of a sidewall of said layer of dielectric material.

9. The trench MOSFET with integrated Schottky diode in a single cell, as recited in claim 1, further comprising a pair of tilt angle regions positioned at two corners defined by said two adjacent body regions and said second trench therebetween, and within said epitaxial layer.

10. The trench MOSFET with integrated Schottky diode in a single cell, as recited in claim 2, further comprising a pair of tilt angle regions positioned at two corners defined by said two adjacent body regions and said second trench therebetween, and within said epitaxial layer.

11. A method of manufacturing a trench MOSFET with integrated Schottky diode in a single cell, comprising the steps of:
forming a plurality of body regions extending in parallel and into an epitaxial layer grown on a substrate;
forming a plurality of first trenches through the body regions respectively and into the epitaxial layer below the body regions;
forming a trench gate within one of the first trenches that is separated by a dielectric layer;
forming a source region between two adjacent first trenches along a top surface of the body regions and the epitaxial layer;
forming a heavy body contact region underneath the source region, and in the body regions and the epitaxial layer positioned between two adjacent first trenches;
forming a second trench between two adjacent body regions through the source region and the heavy body contact region into the epitaxial layer in such a manner that a pair of source regions and a pair of contact regions are positioned at opposite sides of the second trench respectively, so that the source regions, the heavy body contact regions and the two adjacent body regions surround the second trench;
forming a dielectric spacer with proper thickness on the source regions at opposite sides of the first trench and on the first trench therebetween, wherein a size of the heavy body contact regions is determined by that of the dielectric spacer; and
forming an integrated Schottky diode in the second trench by forming a metal layer along a sidewall of the second trench and near a bottom of the second trench.

12. The method, as recited in claim 11, further comprising the step of forming a barrier layer on the metal layer, wherein the second trench is filled with a tungsten plug separated from the metal layer by the barrier layer.

13. The method, as recited in claim 11, wherein a thickness of a bottom of the layer of dielectric material is bigger than that of a sidewall of the layer of dielectric material.

14. The method, as recited in claim 12, wherein a thickness of a bottom of the layer of dielectric material is bigger than that of a sidewall of the layer of dielectric material.

15. The method, as recited in claim 11, wherein the first trench comprises a shield poly within a bottom portion of the layer of dielectric material.

16. The method, as recited in claim 12, wherein the first trench comprises a shield poly within a bottom portion of the layer of dielectric material.

17. The method, as recited in claim 15, wherein a thickness of a bottom of the layer of dielectric material is bigger than that of a sidewall of the layer of dielectric material.

18. The method, as recited in claim 16, wherein a thickness of a bottom of the layer of dielectric material is bigger than that of a sidewall of the layer of dielectric material.

19. The method, as recited in claim 11, further comprising a step of forming a pair of tilt angle regions positioned at two corners defined by the two adjacent body regions and the second trench therebetween, and within the epitaxial layer.

20. The method, as recited in claim 12, further comprising a step of forming a pair of tilt angle regions positioned at two corners defined by the two adjacent body regions and the second trench therebetween, and within the epitaxial layer.
